(19) United States
(12) Patent Application Publication
(10) Pub. No.: US 2012/0114164 A1
(43) Pub. Date: May 10, 2012

(54) Improvements In Or Relating To Surrounds For Audio Drivers

(75) Inventor: Jack Anthony Oclee-Brown, Tonbridge (GB)

(73) Assignee: GP Acoustics (UK) Limited, Maidstone, Kent (GB)

(21) Appl. No.: 13/384,001

(22) PCT Filed: Jul. 16, 2010
(86) PCT No.: PCT/GB2010/001359

§ 371 Date: Jan. 13, 2012

(30) Foreign Application Priority Data
Jul. 17, 2009 (GB) 0912381.1
Mar. 11, 2010 (GB) 1003997.2

(51) Int. Cl. H04R 1/00; H05K 5/02

(52) U.S. Cl. 381/398; 181/153

(57) ABSTRACT

A ring-shaped surround for a loudspeaker is disclosed, in the form of a membrane formed in a shape that, when relaxed (i.e. when not being driven), has a cross sectional shape with a first portion extending in a radial direction for a first distance, a second portion extending in an axial direction for a second distance, and a third portion extending in a radial direction for a third distance, the first and second portions being connected by a first flexible join, and the second and third portions being connected by a second flexible join, the first join having a first radius of curvature that is shorter than at least one of said first and second distances, the second join having a second radius of curvature that is shorter than at least one of said second and third distances. Thus, the surround has a Z-shape, with a first radially extending portion, and a relatively sharp bend leading to an axially-extending portion. The radially outwardly extending portion can have a surface which undulates around its circumference, to provide a stiffening effect to the otherwise planar surface and inhibit resonances. One or more tabs can be provided, extending from a surface of the second portion, in a direction transverse to the local orientation of the second portion. These will adjust the dynamic properties of the surround as required. Typically, the surround will be circular, to fit around a circular driver. However, other shapes are possible.

### CROSS-REFERENCE TO RELATED APPLICATION

This application is a Section 371 National Stage Application of International Application No. PCT/GB2010/001359, filed Jul. 16, 2010 and published as WO 2011/007151A2 on Jan. 20, 2011, the content of which is hereby incorporated by reference in its entirety.

### FIELD OF THE INVENTION

The present invention relates to a surround for an audio driver.

### BACKGROUND ART

The surround is a component on a conventional cone driver. Cone drivers are widely used particularly for the low (20-500 Hz) and midrange (500-3000 Hz) parts of the audio spectrum. The surround provides a flexible air seal between the cone and chassis.

Clearly, the surround must be designed so that it does not impede the motion of the cone—even under large excursions. A common design of surround is the half-roll layout, as depicted in FIGS. 1 and 2. This consists of a annular flange 10, which fits around the (circular) cone and forms a bridge to the (substantially circular) aperture in the chassis into which the cone fits. A flat circular flange 12 extends around the outer circumference of the surround, and allows it to be fixed to the chassis. An inner circumferential flange 14 defines a truncated cone and substantially matches the outer rim of the cone (not shown), allowing the surround to be attached to the cone.

A “half-roll” 16 is provided between (and bridging) the inner flange 14 and the outer flange 12. This is an approximately semi-circular (in section) length of material which initially extends from the inner flange 14 away from the cone and forward of the driver before curving back towards a junction 18 with the outer flange 12. The two flange areas 12, 14 are located at approximately the same axial position. The length of rubber material around the roll shape 16 is greater than the gap 20 between the chassis edge and the cone edge; thus, as the cone moves, the increase in the gap between the cone edge and the chassis edge is accommodated by the extra material around the roll shape 16. Hence, the half roll design impedes the cone very little at low frequencies, when the cone and surround are moving in a simple manner.

The surround is commonly manufactured in a flexible material such as rubber. It is necessary for the material to have a low elasticity, so that the surround does not impede the motion of the cone. However, because of this low elasticity, the bending wavespeed in the material is typically very low. This can cause problems at mid frequencies, where the surround can resonate quite severely. As the surround is quite large in surface area—typically a significant proportion of the cone area—this surround resonance will normally radiate quite effectively. Additionally with a soft cone, such as those made from paper, polypropylene or Kevlar, where the cone is used partly in “breakup” mode, i.e. where the cone is bending in its bandwidth of usage, the surround behaviour has a great effect on the cone motion. In addition, in these modes the surround resonances commonly coincide with bending of the cone edge, which further degrades the radiated frequency response. This is partly because the mechanical impedance presented to the cone edge by the surround typically varies widely with frequency when the surround is close to resonance.

There are a number of techniques which are conventionally employed to try and avoid these issues:

careful material selection for the surround

small flat areas on the inner edge of the surround

changing the thickness of the surround material

adjusting the roll height and width on the surround

However, none of these techniques are guaranteed to be successful in every case. None of these techniques completely eliminate the surround resonance; in the majority of cases, they operate by modifying the behaviour so as to alleviate the problem in that the resonance is not evident in the radiated sound. This approach commonly results in designs which are finely balanced, meaning that if it proves necessary to make a small change of geometry or material for other reasons, the surround resonance problems can re-emerge.

### SUMMARY OF THE INVENTION

In addition to the above difficulties with half-roll surrounds, we have realised that the half-roll 16 presents an irregularity in the surface boundary around the driver. Good loudspeaker design calls for such irregularities to be avoided, with only gentle sweeping curves on the external faces of a loudspeaker. This applies particularly to compound loudspeakers such as that disclosed in GB2236929. Sharp or abrupt discontinuities can adversely affect the propagation of sound emitted by the driver. It would thus be preferable to eliminate the half-roll shape.

In its first aspect, the present invention therefore provides a ring-shaped surround for a loudspeaker, comprising a membrane formed in a shape that, when relaxed (i.e. when not being driven), has a cross-sectional shape that extends generally radially outwardly by a first distance and then changes direction over a second distance to extend axially by a third distance, the second distance being shorter than at least one of the first and third distances.

Another way of presenting this is that the ring-shaped surround for a loudspeaker comprises a membrane formed in a shape that, when relaxed, has a cross sectional shape with a first portion extending in a radial direction for a first distance, a second portion extending in an axial direction for a second distance, and a third portion extending in a radial direction for a third distance, the first and second portions being connected by a first flexible join, and the second and third portions being connected by a second flexible join, the first join having a first radius of curvature that is shorter than at least one of said first and second distances, the second join having a second radius of curvature that is shorter than at least one of said second and third distances.

Thus, the surround has a Z-shape, with a first radially extending portion, and a relatively sharp bend leading to an axially-extending portion. This provides the necessary flexibility to accommodate movement of the loudspeaker cone, but also provides a portion of the surround which can provide a smooth transition between the driver cone and the surrounding loudspeaker housing. The axially-extending portion can be concealed by a suitable housing trim.

The first radially extending portion need not extend strictly perpendicularly outwardly relative to the central axis of symmetry of the driver. Indeed, it is preferably for this portion to continue (to some degree) the flare of the loudspeaker cone. However, it should extend in a direction having a significant radially outward component.

Depending on the size of the driver, the large substantially planar areas of the surround may allow resonances to develop. To resolve this, the radially outwardly extending portion can have a surface which undulates around its circumference—preferably continuously. This provides a stiffening effect to the otherwise planar surface and can inhibit such resonances. The axially extending portion can have a smooth surface. Indeed, we find that a Z-shaped surround with such undulations can offer greater resistance to resonance than a corresponding half-roll surround.

An outer extremity comprising an outwardly-extending flange can also be provided, to help affix the surround to a support that lies around the driver for which the surround is provided. This outwardly-extending flange preferably extends from the second portion. Typically, the above-defined geometry will mean that the outer and inner flanges will be offset axially relative to each other.

One or more tabs can be provided, extending from a surface of the second portion, in a direction transverse to the local orientation of the second portion. These will affect the dynamic properties of the surround and can therefore be positioned and dimensioned so as to tailor the surround as required. The tabs can also attach to a part of the first portion, thereby bridging the bend between the first and second portions and serving to adjust the bending rigidity of the surround. Alternatively, or in addition, tabs can also attach to a part of the outwardly-extending flange for the same purpose.

The second portion preferably extends from the first portion, typically at an outer extremity of the first portion.

In a second aspect, the present invention provides a surround for a loudspeaker driver, comprising an inner flange and an outer flange and a collar of flexible material extending from the inner flange to the outer flange, and at least one tab extending from the collar transversely thereto. The tabs affect the resonant behaviour of the surround, and can be sized and positioned so as to remedy undesirable resonances without necessarily affecting the geometry of surrounding items.

The collar preferably includes at least one curved section. In this case, the tab is ideally attached to the collar either side of the curved section for maximum effect on the resonant behaviour. It can be located on an inner concave section of the collar, or an outer concave section of the collar, or tabs can be provided in both locations.

Indeed, it will be preferred that there is a plurality of tabs in order to provide the necessary effect. These can be distributed radially around the surround, ideally with a high degree of rotational symmetry.

Typically, the outer flange will be flat and the inner flange part-conical as described above.

In a further aspect, the invention relates to a driver for a loudspeaker, comprising a driven cone set in a chassis, and a surround bridging a gap between the cone and the chassis, the surround being as set out above.

In a still further aspect, the invention relates to a loudspeaker including such a driver.

Generally, the invention takes advantage of the high degree of articulation that is possible for a surround having a part that extends radially outwardly of the loudspeaker cone and a part that extends transversely thereto (i.e. generally axially relative to the loudspeaker cone). Deflection of the cone can be accommodated by flexion of the first part and (if necessary) inward deflection of the second part. The present invention therefore encompasses such a design of surround. However, we suspect that in such a simple form, a surround would be too flexible and too prone to resonance. To overcome this, we propose the circumferential undulations and the tabs as discussed above; each assists in controlling the resonant and other dynamic properties of the surround.

Typically, the surround will be circular, to fit around a circular driver. However, other shapes are possible.

### BRIEF DESCRIPTION OF THE DRAWINGS

An embodiment of the present invention will now be described by way of example, with reference to the accompanying figures in which;

FIG. 1 shows a side view of a known half-roll surround;

FIG. 2 shows a section through one edge of a known half-roll surround;

FIG. 3 shows an isometric view of a surround according to the present invention;

FIG. 4 shows a sectional view from the side of a surround according to the present invention;

FIG. 5 shows an enlarged sectional view of an edge of a surround according to the present invention;

FIGS. 6, 7 and 8 show a short section of a surround according to the present invention, in various states of deflection;

FIG. 9 shows the frequency response of a driver with and without blocks on the surround as illustrated in FIGS. 3 to 8;

FIG. 10 shows the surround installed at the edge of a driver contained within a loudspeaker cabinet; and

FIG. 11 shows an alternative design of surround, also installed at the edge of a driver contained within a loudspeaker cabinet.

### DETAILED DESCRIPTION OF ILLUSTRATIVE EMBODIMENTS

This invention seeks to improve on existing loudspeaker surrounds. It first seeks to smooth the transition from the loudspeaker cone to the surrounding cabinet or housing. It also seeks (where necessary) to add significant damping and bending stiffness to the surround for complex deformations, such as those that occur in resonance, but to have little effect on simple deformations, such as those occurring when the cone moves bodily back and forth at low frequencies.

The new surround is manufactured using conventional techniques. A surround which incorporates all preferred aspects of the invention has a new geometry consists of two parts; firstly a thin radially-extending air-sealing surface with a circumferential undulation, and secondly thick blocks of material attached to the thin surface which stiffen the air-sealing surface. The air-sealing surface alone, without the attached blocks and the undulating pattern, might (depending on its dimensions) behave like a conventional surround and have the inherent resonance problems previously discussed. The blocks on the surface of this thin air-sealing part and the circumferential undulation add significant local resistance to bending. The blocks are arranged so that they are not attached to each other directly, they are only joined by the thin membrane. In this way they do not impede the overall flex of the surround, as they can pivot and move with respect to one another. It has been found helpful to overlap the blocks so that the radial section of the air seal is supported by blocks over its entire width.

With some designs it is advantageous to add the blocks only to the part of the surround, where a large motion at resonance is seen. By adjusting the position, number and geometry of the blocks a great deal of control is available over the behaviour of the surround. The presence of the blocks significantly increases the damping and stiffness of the surround to the problematic resonances yet has little effect on the performance of the surround at low frequencies; the cone remains free to move bodily back and forth with little resistance.

The new geometry can be manufactured in one piece, typically by a process such as compression moulding or injection moulding. The blocks can be placed on either side of the air-sealing membrane; this does not appear to affect their behaviour.

It should be understood that the above sets out a design principle in relation to surrounds for cone drivers that can be applied to substantially any surround design and any driver. The projections (tabs, blocks, etc) from the surface of the air-sealing membrane serve to provide a mass, stiffness and damping which affect the manner in which the surround resonates. The undulating pattern also serves to inhibit resonance in the membrane. Thus, previous approaches of adjusting the external shape of the surround become unnecessary as the resonant behaviour of the surround can be affected directly. As noted above, the specific design modifications which were previously carried out in order to cure the surround of undesirable resonances were specific to the design of surround that was being considered. A similar situation exists in this case in relation to the design of the blocks, and therefore it should be understood that the specific embodiment to be described hereafter is one that works for the shape illustrated when used in the context for which it is intended, but which may need to be adjusted depending on the precise shape and context of a different surround. Nevertheless, the principle remains the same.

Notwithstanding this, the invention is particularly advantageous both in terms of the desirable resonant properties which are acquired by a properly designed surround according to the present invention, but also in that the resonant properties of the surround are no longer dependent on the size and shape of the items surrounding it. Therefore, minor changes to those items do not have as dramatic an effect on the resonant properties of the surround as is the case in known driver surrounds. Thus, the surround design is less sensitive to changes in other items, thereby providing a surround whose design is more robust to unrelated design changes.

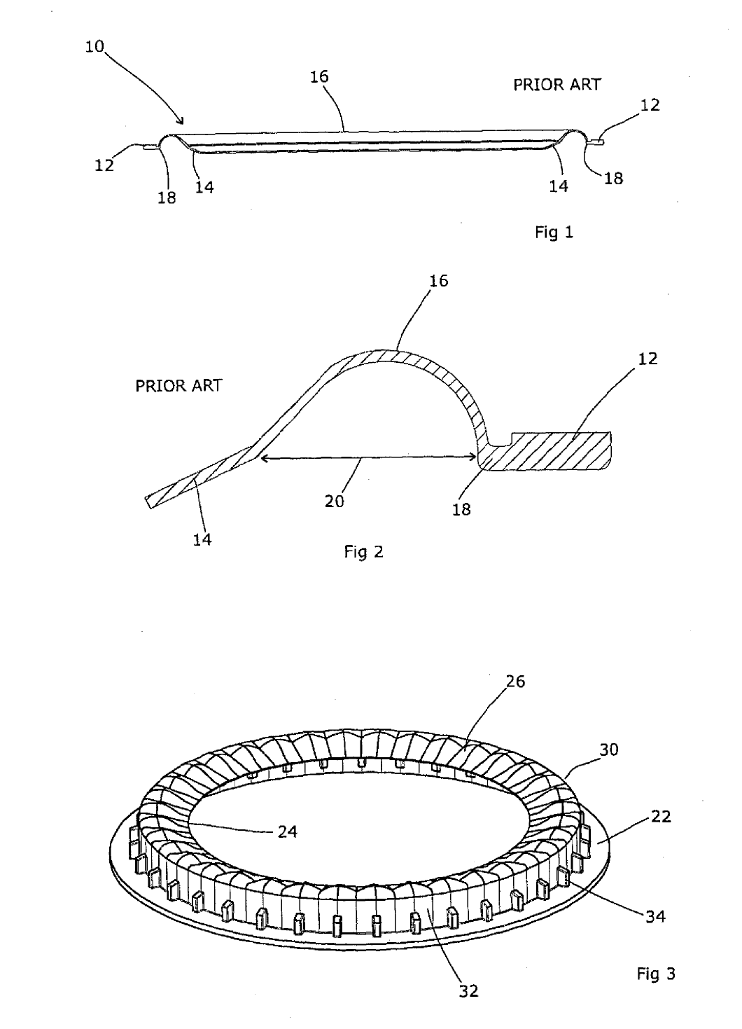

Turning to the illustrated environment, FIG. 3 shows a view of the surround. As with the known surround illustrated in FIGS. 1 and 2, this comprises an outer flange 22 which can be fixed to a chassis (not shown) and an inner flange 24 which can be fitted to the driver cone (not shown). An air-sealing membrane 26 is provided extending from the inner flange 24 to the outer flange 22. As with the classical half roll design illustrated in FIGS. 1 and 2, this initially extends outwardly and slightly upwardly relative to the speaker cone, before reaching an outermost extent 30 at which it curves back down and a side wall 32 extends towards the outer flange 22 which it joins at an approximate right angle 28.

The part of the surround which extends outwardly and slightly upwardly has a circumferential undulating pattern. This takes the form of 36 “bumps” spaced equally around the circumference of the surround, each therefore occupying 10° of the circumference. Generally, we prefer that there are between 18 and 54 bumps, more preferably between 27 and 45. Each bump comprises a locally raised section of surround, merging gently and smoothly into the area around the bump. Each bump is near-sinusoidal in the radial direction, but may be asymmetric in that the merge is more gentle in the direction toward the centre of the ring-shaped surround, creating a lengthening of the bump in that inward direction. The bumps are symmetrical in the circumferential direction, however, so a circumferential section through the surround would show a near-sinusoidal pattern, initially increasing in amplitude as the radius at which the section was being taken increased. The amplitude would reach a maximum at the peak of the bumps before reducing gradually to zero at the outermost extent 30. The bumps are near-sinusoidal (in both radial and circumferential directions) because they are applied as deformations of an existing section. For example, the cross-section shown in FIG. 10 shows no bumps. By applying a deformation to this section, bumps according to embodiments of the invention can be created, but it is unlikely they will have a perfectly sinusoidal profile owing to the constraints of the pre-existing shape.

In any case, the precise shape of the bump is not critical to achieving an adequate performance characteristic, and the present invention is not limited to the particular bump profile illustrated herein.

In one embodiment, however, the amplitude of each bump relative to the undeformed surround (see FIG. 10) is kept below a threshold value. In another embodiment, the amplitude of each bump is the same.

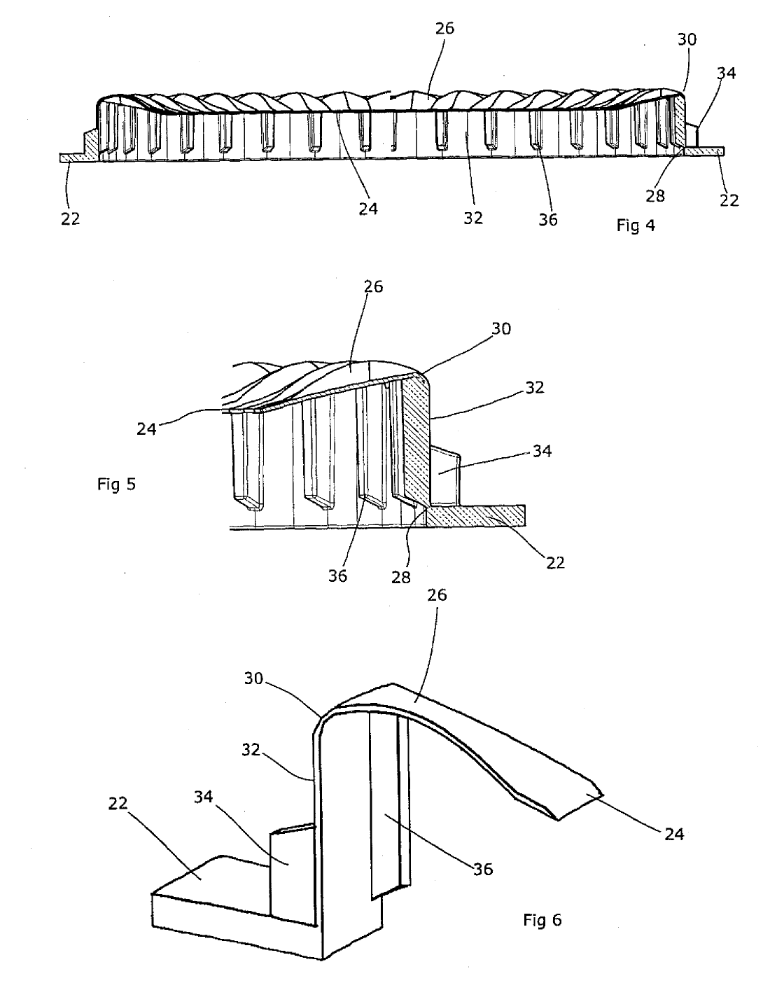

The surround of FIGS. 3-5 also has two sets of tabs or blocks. A first set of blocks 34 are located opposite the joint 28, on the outer concave section of the relevant curve. They thus extend upward from the outer flange 22 and bridge the angle between the outer flange 22 and the air-sealing membrane 26.

A second set of blocks 36 are located on the inner side of the air-sealing membrane 26, on the concave section behind the curve at the outermost extent 30. They are each elongate in nature, extending from the outer extent 30 of the air-sealing membrane alongside the side wall 32 to which they are also attached.

Both sets of blocks 34, 36 extend around the (circular) surround, with individual blocks separated by approximately 10° intervals.

In one embodiment, the relative orientation of the blocks 34, 36 and the bumps is kept the same around the surround. That is, the orientation of one bump relative to its nearest blocks 34, 36 is the same as the orientation of all bumps relative to their respective nearest blocks 34, 36. Thus, the number of bumps in the surround is the same as the number of blocks 34 and the number of blocks 36.

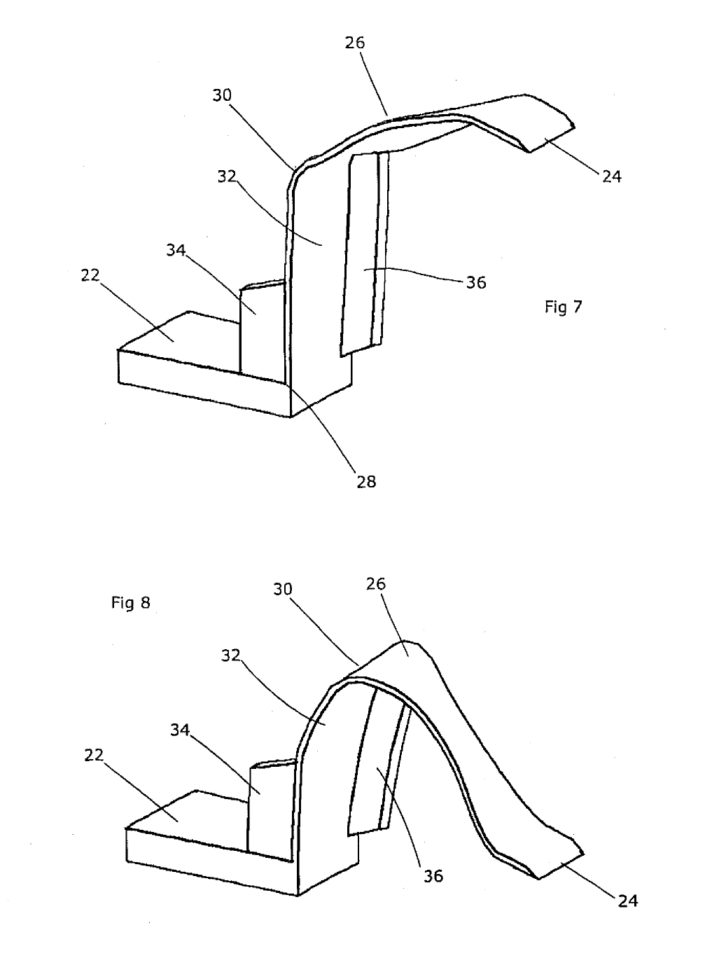

FIGS. 6 to 8 show instantaneous points in the movement of the surround as the cone vibrates. The inner flange 24 moves as required with the movement of the cone. The tabs 34, 36 stretch and flex to permit the surround to accommodate this movement; hence this surround provides the necessary functional requirements of a cone surround, i.e. to provide a continuous air seal around the cone notwithstanding its movement. However, the stiffness of the blocks 34, 36 will impart some additional stiffness to the surround at the locations where the blocks 34, 36 are attached. In addition, the mass of the blocks will affect the inertia of the surround. Both effects will thus affect the dynamic response of the surround.

The stiffness of the blocks will be governed by the material, thickness, and other shape factors of the block. The mass of the block will be determined by its overall size and its material. Thus, by varying the shape and size of the block a high degree of control can be exerted on the dynamic response of the surround. In practice, the material choice will of course often be dictated by the material choice of the remainder of the surround, but some moulding techniques may permit a composite surround.

With this new approach, the surround resonance problem is alleviated to such an extent that it is possible to use shapes of surround which would be very problematic if a conventional approach was taken. For example with the case of a coincident source loudspeaker such as that outlined in WO89/11201, it is advantageous for the surround of the cone driver to be a continuation of the cone shape so that it does not affect the sound radiated from the tweeter. A conventional half roll geometry is not ideal for this situation. If the approach of the present invention is used, it is possible to use a shape of surround which would ordinarily perform very poorly, but does not as a result of the supporting sections. The supporting sections are able to modify the surround performance so that the surround resonance problem is not present.

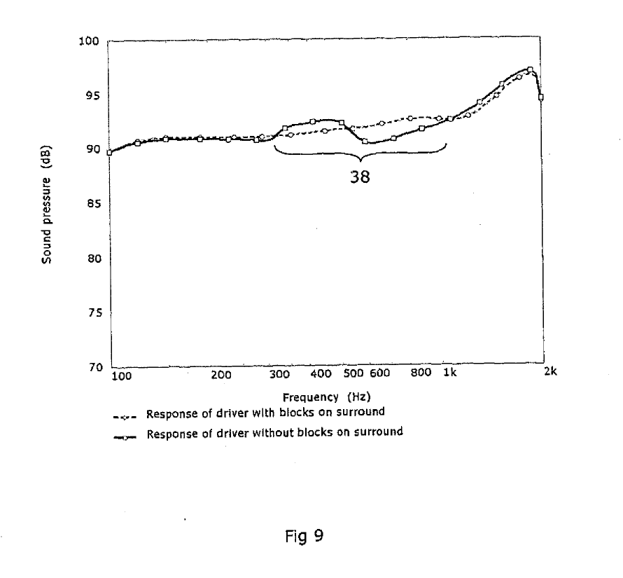

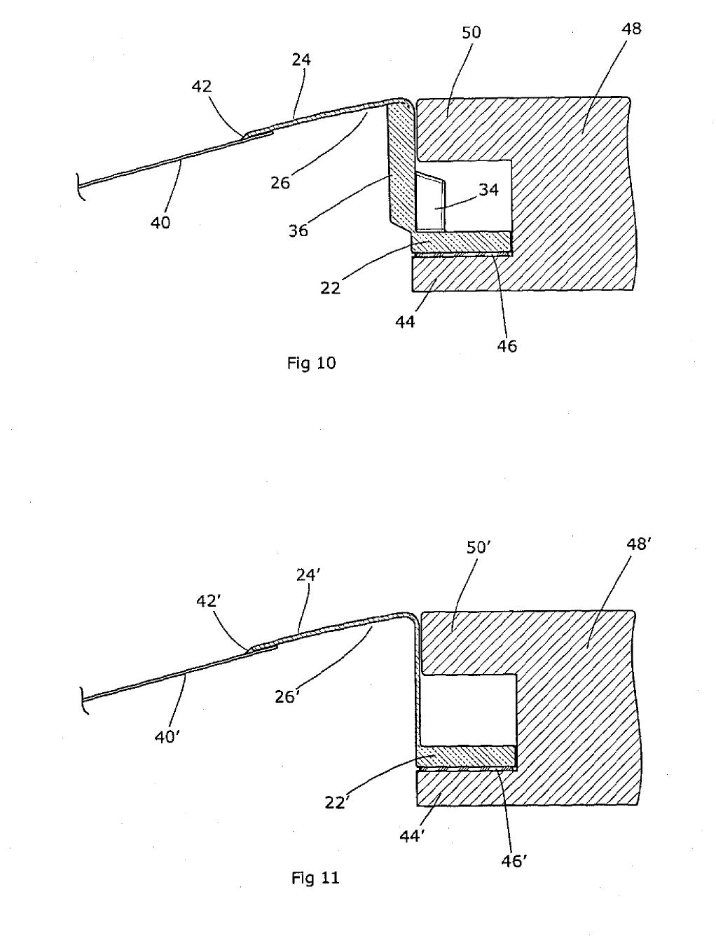

FIG. 9 shows the frequency response of a driver with and without blocks on the surround as illustrated in FIGS. 3 to 8. This was obtained via a FEM/BEM simulation, calculating the pressure response 1 m from the surround, on its central axis, with a 2.83V input. The surround without blocks shows a distinct anomaly at 38, over a significant portion of the response curve. This is entirely eliminated in the curve for the surround with blocks. As a result, the surround without blocks is usable up to about 300 Hz whereas the surround with blocks is usable up to about 1 kHz.

FIG. 10 shows the surround as described above in position within a loudspeaker. The loudspeaker comprises a driven cone 40, an outer extremity of which is shown in FIG. 10. The inner flange 24 of the surround is attached to an outer edge of the cone 40 in a sealed manner, for example using a small amount of adhesive 4′. The outer flange 22 of the surround is affixed to a ledge 44 via a layer of adhesive 46, or by a clamp or other fixing. The ledge 44 is formed within a larger loudspeaker cabinet 48 which houses the remainder of the driver 40 together with any other drivers that are required. A trim section 50 extends over the outer flange 22, in front of the outer flange 22 and the second set of blocks 36. It extends up to (but not quite touching) the air-sealing membrane 26 but is not attached thereto, thereby allowing the air-sealing membrane to flex inwardly as required.

FIG. 11 shows a simpler embodiment of the invention. The surround is the same as that described above save that the undulations of the inner flange 24 are absent and the blocks 34, 36 are absent. Thus, the loudspeaker comprises a driven cone 40′, an outer extremity of which is shown. The inner flange 24′ of the surround is attached to an outer edge of the cone 40′ in a sealed manner, for example using a small amount of adhesive 42′. The outer flange 22′ of the surround is affixed to a ledge 44′ via a layer of adhesive 46′, or by a clamp or other fixing. The ledge 44′ is formed within a larger loudspeaker cabinet 48′ which houses the remainder of the driver 40′ together with any other drivers that are required. A trim section 50′ extends over the outer flange 22′, in front of the outer flange 22′. It extends up to (but not quite touching) the air-sealing membrane 26′ but is not attached thereto, thereby allowing the air-sealing membrane to flex inwardly as required.

In the context of a loudspeaker with smaller dimensions and/or a smaller excursion, a more simple surround such as is shown in FIG. 11 may be sufficiently resistant to resonances (and the like). Where the dimensions are relatively small, the surround resonances are usually sufficiently high in frequency that they will not cause response irregularities in the working band of the driver. Where this is not the case, either the undulations on the inner flange 24, or the blocks 34, 36 can be re-instated, or other measures taken, as necessary.

It will of course be understood that many variations may be made to the above-described embodiment without departing from the scope of the present invention.

Although the present invention has been described with reference to preferred embodiments, workers skilled in the art will recognize that changes may be made in form and detail without departing from the spirit and scope of the invention.

1. A ring-shaped surround for a loudspeaker, comprising a membrane formed in a shape that, when relaxed, has a cross-sectional shape with a first portion extending in a radial direction for a first distance, a second portion extending in an axial direction for a second distance, and a third portion extending in a radial direction for a third distance,
the first and second portions being connected by a first flexible join, and the second and third portions being connected by a second flexible join, the first join having a first radius of curvature that is shorter than at least one of said first and second distances, the second join having a second radius of curvature that is shorter than at least one of said second and third distances.

2. The surround according to claim 1, wherein the radially outwardly extending portion has a surface which undulates around its circumference.

3. The surround according to claim 1, wherein the axially extending portion has a smooth surface.

4. The surround according to claim 1, having an outer extremity comprising an outwardly-extending flange.

5. The surround according to claim 4 in which the outwardly-extending flange extends from the axially extending portion.

6. The surround according to claim 1, further comprising at least one tab extending from a surface of the second portion, in a direction transverse to the local orientation of the second portion.

7. The surround according to claim 6 in which the at least one tab also attaches to a part of the first portion.

8. The surround according to claim 6 in which the at least one tab also attaches to a part of the outwardly-extending flange.

9. The surround according to claim 6, comprising a plurality of tabs, and wherein a number of said tabs is equal to a number of said circumferential undulations.

10. The surround according to claim 1 in which the second portion extends from the first portion.

11. A surround for a loudspeaker driver, comprising an inner flange and an outer flange and a collar of flexible material therebetween, at least part of which extends transversely relative to the inner flange, and at least one tab extending outwardly from the collar transversely thereto.

12. The surround according to claim 11 in which the collar includes at least one arcuate section.

13. The surround according to claim 12 in which the tab is attached to the collar either side of the arcuate section.

14. The surround according to claim 12 in which the tab is located on an inner concave section of the collar.

15. The surround according to claim 12 in which the tab is located on an outer concave section of the collar.

16. The surround according to claim 11 in which there are a plurality of tabs.

17. The surround according to claim 16 in which the plurality of tabs are distributed radially around the surround.

18. The surround according to claim 11 in which the outer flange is flat.

19. The surround according to claim 11 in which the inner flange is part-conical.

20. A driver for a loudspeaker, comprising a driven cone set in a chassis, and a surround bridging a gap between the cone and the chassis, the surround being according to any one of the preceding claims.

21. The loudspeaker including a driver according to claim 20.

22. (canceled)
